(19) United States
(12) Patent Application Publication
(10) Pub. No.: US 2017/0331427 A1
(43) Pub. Date: Nov. 16, 2017

(54) Temporary Field Assisted Passivation For Testing Of Partially Processed Photovoltaic Solar Cells

(71) Applicant: SOLEXEL, INC., Milpitas, CA (US)

(72) Inventor: Mehrdad M. MOSLEHI, Los Altos, CA (US)

(21) Appl. No.: 15/524,929

(22) PCT Filed: Nov. 9, 2015
(86) PCT No.: PCT/US15/59796

§ 371 Date: May 5, 2017

Related U.S. Application Data
(60) Provisional application No. 62/077,150, filed on Nov. 7, 2014.

(51) Int. Cl. H02S 50/15; H01L 31/0224; H01L 31/02; H01L 31/05; G01R 1/04

(52) U.S. Cl. CPC H02S 50/15; H01L 31/0516; G01R 1/0408; H01L 31/02008; H01L 31/022475

(57) ABSTRACT

A method for electrical testing of a back contact solar cell applies a first side of a temporary passivation sheet to a frontside of a back contact solar cell, the first side of the temporary passivation sheet comprising at least a transparent dielectric layer. The temporary passivation sheet having a second side opposite the first side and comprising at least a transparent conductive coating. A voltage is applied between the transparent conductive coating and base metallization of the back contact solar cell. The frontside of the back contact solar cell is illuminated through the transparent conductive coating and the transparent dielectric layer. Electrical testing is performed on the back contact solar cell. The temporary passivation sheet is removed from the frontside of the back contact solar cell.

### CROSS-REFERENCE TO RELATED APPLICATIONS

This application claims the benefit of U.S. provisional patent application 62/077,150 filed on Nov. 7, 2014, which is hereby incorporated by reference in its entirety.

### FIELD OF THE INVENTION

The present disclosure relates in general to the fields of solar photovoltaics (PV), and more particularly to solar photovoltaic cell fabrication.

### BACKGROUND

Efficient photovoltaic solar cell and module fabrication may require accurate solar cell testing and measurement to determine solar cell performance (e.g., efficiency) characteristics and electrical parametrics such as, for example, cell current, voltage, and fill factor. Solar cell performance characteristics and electrical parametrics information may be used, for example, to ensure solar cell quality and for sorting and binning solar cells. Specific solar cell performance characteristics and electrical parametrics such as short circuit current (I_{SC}), short circuit voltage (V_{SC}), and fill factor may be used, for example, to determine whether a particular solar cell meets cell performance thresholds, to sort and bin solar cells, and to match solar cells for use in a certain module.

Obtaining accurate solar cell performance characteristics and electrical parametrics such as, for example, current, voltage, and fill factor, prior to solar cell completion or in-line during fabrication from partially processed solar cells may be particularly advantageous for efficient solar cell and module fabrication. However, accurate solar cell performance characteristics and electrical parametrics are often challenging to determine as the solar cell performance characteristics and electrical parametrics of partially processed solar cells may be inconsistent with the completed or fully processed solar cell as partially processed solar cells may lack certain solar cell structural elements of completed or fully processed solar cells (e.g., frontside/sunnyside passivation) which affect solar cell performance characteristics and electrical parametrics. Additionally, determining solar cell performance characteristics and electrical parametrics of partially process solar cells during solar cell fabrication (i.e., in-line) while maintaining mechanical yield and throughput may be particularly challenging.

### BRIEF SUMMARY OF THE INVENTION

Therefore, a need has arisen for improved solar cell performance and electrical parametric testing of partially processed solar cells. In accordance with the disclosed subject matter, solar cell performance and electrical parametric testing for partially processed solar cells is provided which substantially eliminates or reduces disadvantages and deficiencies associated with previously developed solar cell performance and electrical parametric testing.

According to one aspect of the disclosed subject matter, a method for electrical testing of a back contact solar cell applies a first side of a temporary passivation sheet to a frontside of a back contact solar cell, the first side of the temporary passivation sheet comprising at least a transparent dielectric layer. The temporary passivation sheet having a second side opposite the first side and comprising at least a transparent conductive coating. A voltage is applied between the transparent conductive coating and base metallization of the back contact solar cell. The frontside of the back contact solar cell is illuminated through the transparent conductive coating and the transparent dielectric layer. Electrical testing is performed on the back contact solar cell. The temporary passivation sheet is removed from the frontside of the back contact solar cell.

According to another aspect of the disclosed subject matter, a back contact solar cell test structure comprises a back contact solar cell having a solar cell substrate having a light receiving frontside and a backside having base and emitter regions. Base metallization and emitter metallization on the substrate backside contacts the base regions and emitter metallization contacting the emitter regions. A temporary passivation sheet has at least a transparent dielectric and a transparent conductive coating. An electrical power supply is electrically connected to the transparent conductive coating and electrically connected to the solar cell substrate by the base metallization. A solar cell electrical tester is electrically connected to the base metallization and the emitter metallization.

According to another aspect of the disclosed subject matter, a solar cell electrical tester for electrical testing of partially processed solar cells comprises a solar simulator illumination source, a temporary passivation sheet having at least a transparent dielectric and a transparent conductive coating, and a chuck having base electrical probes and emitter electrical probes. An electrical power supply is electrically connected to the transparent conductive coating and the base electrical probes. A solar cell electrical tester is electrically connected to the base electrical probes and the emitter electrical probes.

These and other aspects of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGUREs and detailed description. It is intended that all such additional systems, methods, features and advantages that are included within this description, be within the scope of any claims.

### BRIEF DESCRIPTION OF THE DRAWINGS

The features, natures, and advantages of the disclosed subject matter may become more apparent from the detailed description set forth below when taken in conjunction with the drawings in which like reference numerals indicate like features and wherein:

FIG. 1 is a cross-sectional diagram of a temporary passivation before application to a partially processed back contact back junction solar cell;

FIG. 2 is a cross-sectional diagram of a temporary passivation after application to partially processed back contact back junction solar cell for temporary field assisted passivation;

FIG. 3 is a diagram showing a partially processed back contact solar cell and in-line IV measurement structure before application of temporary passivation; and

FIG. 4 is a diagram showing a partially processed back contact solar cell and in-line IV measurement structure after application of temporary passivation.

### DETAILED DESCRIPTION

The following description is not to be taken in a limiting sense, but is made for the purpose of describing the general principles of the present disclosure. The scope of the present disclosure should be determined with reference to the claims. Exemplary embodiments of the present disclosure are illustrated in the drawings, like aspects and identifiers being used to refer to like and corresponding parts of the various drawings.

And although the present disclosure is described with reference to specific embodiments and components, one skilled in the art could apply the principles discussed herein to other solar cell structures and materials (e.g., monocrystalline silicon or multi-crystalline silicon absorbers and front or back contact solar cells), fabrication processes (e.g., various testing methods and materials such as solar cell IV testers having distributed electrical base and emitter probes), as well as alternative technical areas and/or embodiments without undue experimentation.

The present application provides solar cell testing and measurement solutions for in-line solar cell performance (e.g., efficiency) characteristics and electrical parametrics testing of partially processed solar cells through the formation of a temporary field assisted front surface passivation. As provided herein, in-line or partially processed solar cell electrical parametrics and efficiency measurements may be determined with relatively strong correlation to end-of-the-line or completed solar cell electrical parametrics and efficiency measurements. The solar cell testing and measurement solutions provided may be particularly advantageous for any solar cell application where solar cell front surface passivation is not formed when in-line solar cell testing or testing and solar cell binning/sorting is desired. For example, in certain back contact solar cell fabrication flows solar cell backside processing may be completed through the formation of base and emitter metallization or electrodes and prior to front surface passivation.

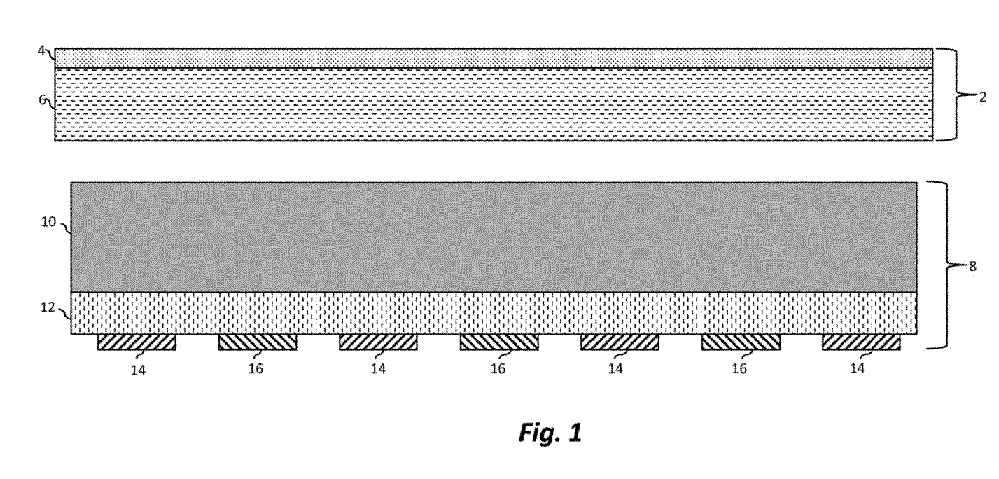

In accordance with the disclosed subject matter, a temporary field assisted passivation is applied to a partially processed solar cell processed through base and emitter metallization for in-line solar cell electrical parameter and efficiency testing. The temporary passivation layer or sheet or membrane or film may have an optically transparent dielectric layer and an optically transparent electrically conductive layer. FIG. 1 is a cross-sectional diagram of a temporary passivation before application to a partially processed back contact back junction solar cell. Temporary passivation 2 is formed of transparent conductive oxide 4 on transparent dielectric 6. Partially processed back contact back junction solar cell 8 is formed of n-type semiconductor absorber 10, for example a silicon absorber such as an n-type silicon wafer. Back contact cell structure 12 of partially process back contact back junction solar cell 8 may include base and emitter regions and backside passivation such as a dielectric layer. Base fingers 14 contact the back contact back junction solar cell base regions through the backside passivation and emitter fingers 16 contact the back contact back junction solar cell emitter regions through the backside passivation. Base electrode fingers 14 and emitter electrode fingers 16 may be in an interdigitated pattern of base and emitter fingers such as those in an interdigitated back contact (IBC) solar cell.

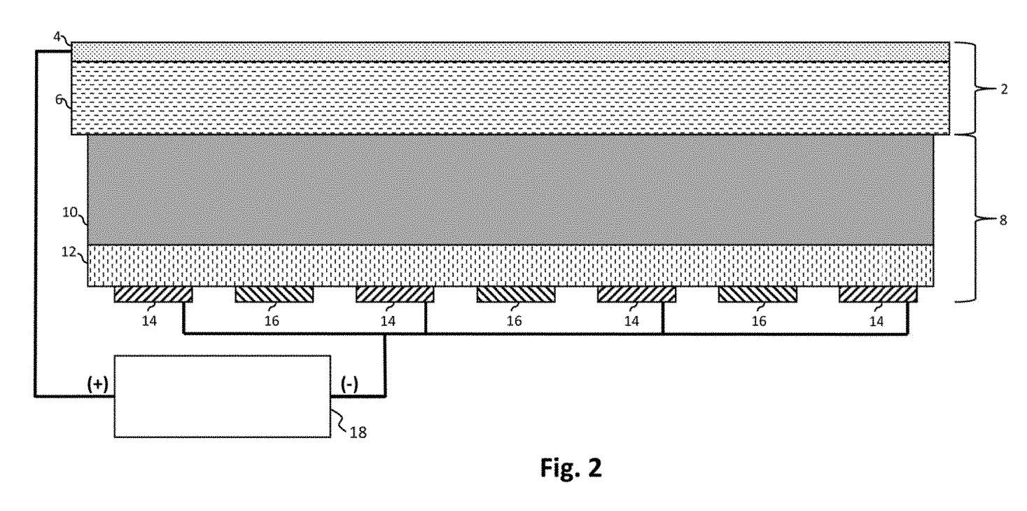

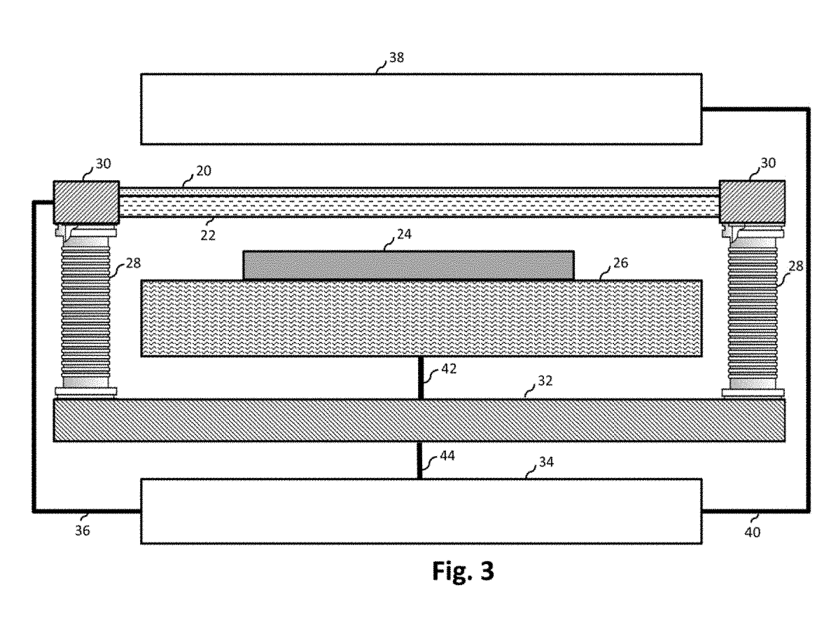

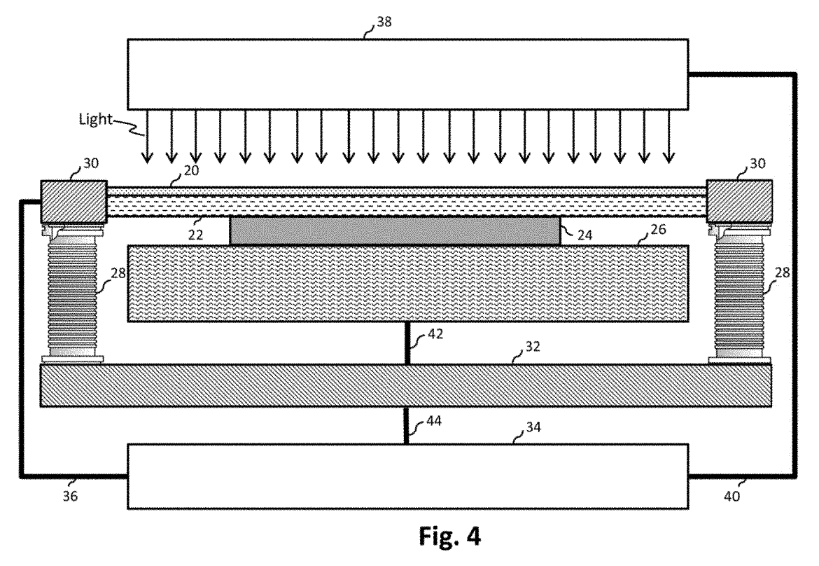

The temporary passivation is applied, advantageously in soft conformal contact, with the front surface of the partially process solar cell after base and emitter metallization. The transparent dielectric of the temporary passivation may be a sheet or membrane or film, for example a thin (e.g., having a thickness in the range of 25 μm to 50 μm but may be as thin as 12.5 μm or thinner) highly transparent flexible (e.g., conformal for conformal contact to the front surface of the solar cell) electrically insulating material such as ethylene-tetrafluoroethylene (ETFE), fluorinated ethylene propylene (FEP), and commercially available materials such as Mylar® by Dupont Tejjin Films, TEONEX® PEN film by Dupont Tejjin Films, or UV-stabilized Melinex® polyester film by Dupont Tejjin Films. Although other suitable transparent material sheets may be used. The transparent dielectric frontside (i.e., the transparent conductive dielectric side opposite the side applied to the front surface of the solar cell) of the transparent dielectric (e.g., a sheet) is coated with an optically transparent electrically conductive layer (e.g., having a thickness in the range of tens to hundreds of nanometers) such as a transparent conductive oxide (TCO) layer such as indium tin oxide (ITO) or other suitable transparent metal oxide layers. The optically transparent electrically conductive layer (e.g., TCO) acts as an electrode and has an electrode electrical connection (electrode electrical connection not shown in FIGS. 1 and 2 but may, for example be a connection such as a multiple wire connection to the optically transparent conductive layer or a connection structure such as metal support frame 30 in FIGS. 3 and 4) for application of a voltage between such as a DC bias voltage V (for instance, positive voltage applied to a transparent oxide and a negative voltage applied to base metallization/electrodes in a case of an IBC cell with n-type base). In other words, a temporary capacitor is formed with the optically transparent electrically conductive layer and the bulk semiconductor absorber (e.g., silicon) serving as the capacitor electrodes and the transparent dielectric serving the capacitor insulating layer sandwiched between the electrodes.

FIG. 2 is a cross-sectional diagram of temporary passivation 2 after application to partially processed back contact back junction solar cell 8 for temporary field assisted passivation. Transparent dielectric 6 is applied to the front surface of partially processed back contact back junction solar cell 8. DC power supply 18 connects to the electrode connection of transparent conductive oxide 4 and base metallization 14. Positive DC voltage is applied to transparent conductive oxide 4 (e.g., ITO) electrode for electrostatic clamping and field-assisted passivation—in other words transparent conductive oxide 4 acts as an electrode forming a capacitor with n-type semiconductor absorber 10. DC power supply may be a high voltage current limited DC power supply (e.g., a 3 kV and 1 mA max DC power supply). The voltage is applied such that sufficient field assisted/enhanced passivation is achieved. The level of positive DC bias voltage (e.g., in the case of an IBC solar cell with n-type base and as shown in FIG. 2) may depend on the thickness and dielectric constant of the temporary passivation transparent dielectric (e.g., transparent dielectric sheet material) as well as the required level of mirror charge to be induced on the solar cell sunnyside/frontside. In the case of an IBC solar cell with n-type base and as shown in FIG. 2, the negative electrode for the applied DC bias is connected to the base electrode and the positive electrode for the applied DC bias is connected to the transparent conductive oxide. In other words the base electrode is connected to the semiconductor absorber bulk (e.g., n-type silicon) and the bias is applied between the transparent conductive oxide and the semiconductor absorber bulk via the base metallization (i.e., base electrode).

The solar cell is then illuminated (e.g., one SUN) through the temporary passivation and testing is performed, for example solar cell IV testing. A solar cell electrical tester such as an IV tester may measure solar cell parameters such as I_{SC}, fill factor, and V_{SC} (I_{SC} may be particularly advantageous to measure for solar cell quality and solar cell sorting/binning) of the partially processed solar cell with the assistance of the temporary passivation to determine projected completed or fully processed solar cell performance. The positive DC voltage may be removed (e.g., grounded) and the transparent conductive oxide (e.g., ITO) electrode may be discharged with respect to the base metallization after testing and measurement has been performed. Solar cell characteristic information may be determined and used to determine if a particular solar cell meets cell performance thresholds, to sort and bin solar cells and to match solar cells for use in a certain module (e.g., match using solar cell I_{SC}).

The transparent dielectric of the temporary passivation may be a dielectric film, sheet, or membrane for example having characteristics such as: a thickness in the range of approximately 25 μm to 50 μm (in some instances the dielectric film may have a thickness as thin as 12.5 μm or thinner); superior optical transparency and UV stability; a relatively large breakdown field to apply a higher voltage at a given thickness without dielectric breakdown which may lead to ARC-ing through the transparent dielectric (e.g., a dielectric strength of greater than or equal to 5000V per mil or 200V per micron); durability; and, advantageously may have a relatively larger dielectric constant as thinner films with larger dielectric constants may reduce the applied bias voltage requirement to achieve effective field-assisted passivation (e.g., a relative dielectric constant greater than or equal to 2.0). Additionally, the transparent dielectric (e.g., a dielectric film) may have flexibility for conformal electrostatic attachment to the unfinished frontside of the partially processed back contact solar cell. The transparent dielectric (e.g., a dielectric film) may have superior adhesion for transparent conductive layer (e.g., ITO) deposition on its surface. The transparent dielectric (e.g., a dielectric film) may be mechanically robust and durable to last through numerous (e.g., 1000's) in-line solar cell measurements and soft contact cycles. The transparent dielectric (e.g., a dielectric film) may have corona discharge resistance for DC applications. The transparent dielectric (e.g., a dielectric film) may have relatively high volume resistivity (e.g., greater than approximately 10¹⁷Ω.cm) at room temperature. The transparent dielectric (e.g., a dielectric film) may have superior insulation resistance at room temperature.

After the transparent dielectric of the temporary passivation sheet or membrane is placed on the partially-processed solar cell frontside and the DC bias voltage is applied to the transparent conductive layer (e.g., a transparent conductive oxide such as ITO), the transparent dielectric clamps itself to the cell surface electrostatically (i.e., clamping under attractive electrostatic force between the capacitor plates formed of bulk semiconductor and the transparent conductive oxide) and conformally with uniform soft mechanical contact throughout the surface. After the electrostatic contact is made, in-line solar cell electrical parameters and efficiency testing and measurements may be performed such as solar cell current voltage (IV) testing and measurement. After testing, to remove the temporary passivation sheet the voltage is discharge to release the electrostatic force between the transparent dielectric and the front surface of the solar cell.

FIGS. 3 and 4 are diagrams showing an in-line solar cell electrical parametric and efficiency testing and measurement structure for solar cell IV testing and measurement. FIG. 3 shows a partially processed back contact solar cell and in-line IV measurement structure before application of temporary passivation. As shown in FIG. 3, a temporary passivation sheet formed of transparent dielectric film 22 and conductive oxide coating (e.g., ITO) 20 on transparent dielectric film 22. The temporary passivation sheet is supported by metallic support frame 30 attached to up/down actuator 28. Metallic support frame 30 provides electrical connection to conductive oxide 20 and may be a peripheral support frame encompassing or nearly encompassing the conductive oxide coating and transparent dielectric film thus supporting the film and providing electrical connection to the conductive oxide coating for a relatively uniform and equi-potential electrode (i.e., the voltage being substantially the same throughout the entire conductive oxide, serving as an electrode). Up/down actuator 28 is controlled by computer controller 32 for lifting and lowering the temporary passivation and metallic support frames to and from partially processed back contact solar cell 24 on computer controlled IV tester chuck 26 (e.g., vacuum chuck) having distributed electrical probes (e.g., positive for emitter electrodes and negative for base electrodes). IV tester 34 (e.g., an IV tester including IV tester instrumentation electronics, power suppliers, and system control computer) is electrically connected to the metallic frame support 30 by temporary passivation connector 36 and is connected to and communicates with solar simulator illumination source 38 (e.g., a solar simulator illumination source capable of providing one SUN irradiance) by solar simulator illumination source control link and electrical connection 40. IV tester 34, computer controller 32, and tester chuck 26 are interconnected for control, communication, and electrical connection—for example via control link and electrical connections 42 and 44. Temporary passivation connector 36 may provide voltage to the oxide layer (positive voltage) from IV tester 34 and discharge the capacitor to a ground thus removing the electric field and detaching the temporary passivation sheet formed of transparent dielectric film 22 and conductive oxide coating 20.

FIG. 4 is consistent with FIG. 3 and showing a partially processed back contact solar cell and in-line IV measurement structure after applying voltage bias and application of temporary passivation. Solar simulator illumination source 38 provides light for in-line IV testing during voltage bias application.

The applied bias voltage (e.g., an applied DC bias of 100V up to a few kilo-volts) may be dependent on the transparent dielectric material and the required induced charge. In other words, in some instances the bias voltage may depend on the required charge density on the transparent oxide (e.g., ITO) electrode of the temporary passivation capacitor for sufficient field-assisted passivation. For example, assume a temporary passivation transparent dielectric FEP sheet with the following properties: an FEP sheet with a thickness of T=12.5 μm and dielectric constant of εᵣ≈2.05; capacitance per unit area of FEP sheet: C=ε₀. εᵣ/T, wherein ε₀=8.85×10⁻¹² F/m; ITO electrode charge density: Q=C.V, wherein Q is the ITO charge per unit area, C is the TP sheet capacitance per unit area, and V is the applied voltage; Q=[ε₀. εᵣ/T].V wherein Q is the charge density in coulombs per unit area; charge density represented as the number of electrons per unit area (N) is obtained by dividing C by the electron charge (1.60×10⁻¹⁹ coulombs): N=Q/(1.6×10⁻¹⁹ coulombs)=[(ε₀. εᵣ.V)/(1.6×10⁻¹⁹ T)]. For a given N value, V may be calculated as follows: V=(1.6×10⁻¹⁹ T.N)/(ε₀. εᵣ). For effective field-assisted passivation, N should be at least 1×10¹² cm⁻² or 1×10¹⁶ m⁻². Assuming an FEP thickness of 12.5 μm, the bias voltage may be calculated as: V=(1.6×10⁻¹⁹ C. 12.5×10⁻⁶ m. 1×10¹⁶ m⁻²)/(8.85×10⁻¹² F/m. 2.05) so V=(2.0×10⁻⁸ C/m)/(18.14×10⁻¹² F/m)≈1100 V. Therefore, for a 12.5 μm thick FEP layer with ITO coating on one side, one may need to apply a DC bias voltage of about 1100 V for temporary passivation creating a mirror charge density of N=1×10¹² cm⁻² on the silicon side. For a lower N value of N=1×10¹¹ cm⁻², the required applied bias voltage would be V≈110 V.

Additionally, in some instances, the following temporary passivation conditions may be advantageous. For the transparent dielectric, use a suitable 1 mil (25 μm) thick transparent polyester material (e.g., Mylar® by Dupont Tejjin). For Mylar® by Dupont Tejjin, εᵣ=3.3. Coat one side of the Mylar® by Dupont Tejjin film with a thin ITO layer for the transparent conductive oxide. Attach the ITO-coated Mylar® by Dupont Tejjin layer to a metallic support frame with the metallic support frame also being used as the ITO-connected electrode for positive DC bias. For effective field-assisted passivation, set the DC bias voltage for N to be at least 1×10¹² cm⁻² or 1×10¹⁶ m⁻². Assuming a Mylar® by Dupont Tejjin thickness of 25 μm, the bias voltage may be calculated as: V=(1.6×10⁻¹⁹ C. 25×10⁻⁶ m. 1×10¹⁶ m⁻²)/(8.85×10⁻¹² F/m. 3.3) so V=(4.0×10⁻⁸ C/m)/(29.21×10⁻¹² F/m)≈1370 V. Therefore, for a 25 μm thick Mylar® by Dupont Tejjin film with ITO coating on one side, one may need to apply a DC bias voltage of about 1370 V for temporary passivation creating a mirror charge density of N=1×10¹² cm⁻² on the silicon side.

Additionally, to calculate how long it may take to charge the ITO electrode from 0 V to target voltage, consider: I=C ΔV/Δt then Δt=C ΔV/J=(ε₀.ε₀.A /T).(ΔV/I), wherein A is the ITO area. Assume electrode area of A=20 cm×20 cm=0.04 m² and power supply current of 1 mA then Δt=(3.3×8.85×10⁻¹² F/m×0.04 m²×1370 V)/(25×10⁻⁶ m×1×10⁻³ A) so Δt=64×10⁻³ s=64 ms. In some instances, 64 ms may be considered a quite fast electrode charging time and acceptable. In some instances, the electrode charging time may be further slowed down to approximately one second by adding a series resistor to minimize risk of corona discharge.

After parametric values such as I_{SC} have been determined, the solar cell may then be sorted and binned for example, for solar cell quality control and subsequent cell characteristic matching and lamination into a module such as a monolithic module.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

1. A method for electrical testing of a back contact solar cell, comprising:
applying a first side of a temporary passivation sheet to a frontside of a back contact solar cell, said first side of said temporary passivation sheet comprising at least a transparent dielectric layer, said temporary passivation sheet having a second side opposite said first side and comprising at least a transparent conductive coating;
applying a voltage between said transparent conductive coating and base metallization of said back contact solar cell;
illuminating said frontside of said back contact solar cell through said transparent conductive coating and said transparent dielectric layer;
performing electrical testing on said back contact solar cell; and
removing said temporary passivation sheet from said frontside of said back contact solar cell.

2. The method for measuring an electric parametric value from a back contact solar cell of claim 1, wherein said temporary passivation sheet comprises a transparent dielectric layer having a thickness less than 50 μm and said transparent conductive oxide is indium tin oxide.

3. The method for measuring an electric parametric value from a back contact solar cell of claim 1, wherein said voltage is in the range of hundreds to thousands of volts.

4. The method for measuring an electric parametric value from a back contact solar cell of claim 1, wherein said electrical testing measures short circuit current, open circuit voltage, and fill factor of said solar cell.

5. A back contact solar cell test structure, comprising:
a back contact solar cell comprising:
a solar cell substrate having a light receiving frontside and a backside, said backside comprising base and emitter regions;
base metallization and emitter metallization on said substrate backside, said base metallization contacting said base regions and said emitter metallization contacting said emitter regions;
a temporary passivation sheet having at least a transparent dielectric and a transparent conductive coating;
an electrical power supply electrically connected to said transparent conductive coating and electrically connected to said solar cell substrate by said base metallization; and
a solar cell electrical tester electrically connected to said base metallization and said emitter metallization.

6. The back contact solar cell test structure of claim 5, wherein said transparent dielectric is dielectric film having a thickness of less than or equal to approximately 50 μm.

7. The back contact solar cell test structure of claim 5, wherein said transparent dielectric is dielectric film having a thickness of less than or equal to approximately 25 μm.

8. The back contact solar cell test structure of claim 5, wherein said transparent dielectric is dielectric film having a thickness of less than or equal to approximately 12.5 μm.

9. The back contact solar cell test structure of claim 5, wherein said transparent conductive coating is a transparent conductive oxide.

10. The back contact solar cell test structure of claim 9, wherein said transparent conductive oxide is indium tin oxide.

11. The back contact solar cell test structure of claim 5, wherein said temporary passivation sheet comprises a transparent dielectric layer having a thickness less than 50 μm and said transparent conductive coating is indium tin oxide.

12. The back contact solar cell test structure of claim 5, wherein said solar cell electrical tester is a solar cell IV tester with a solar light simulator.

13. The back contact solar cell test structure of claim 5, further comprising a metal frame around the periphery of said temporary passivation sheet and electrically contacting said transparent conductive coating.

14. A solar cell electrical tester for electrical testing of partially processed solar cells, comprising:
a solar simulator illumination source;
a temporary passivation sheet having at least a transparent dielectric and a transparent conductive coating;
a chuck having base electrical probes and emitter electrical probes;
an electrical power supply electrically connected to said transparent conductive coating and said base electrical probes; and
a solar cell electrical tester electrically connected to said base electrical probes and said emitter electrical probes.

15. The back contact solar cell test structure of claim 14, wherein said transparent conductive coating is a transparent conductive oxide.

16. The back contact solar cell test structure of claim 15, wherein said transparent conductive oxide is indium tin oxide.

17. The back contact solar cell test structure of claim 14, further comprising a metal frame around the periphery of said temporary passivation sheet and electrically contacting said transparent conductive coating.

18. The back contact solar cell test structure of claim 14, wherein said temporary passivation sheet comprises a transparent dielectric layer having a thickness less than 50 μm and said transparent conductive coating is indium tin oxide.

19. The back contact solar cell test structure of claim 14, wherein said solar cell electrical tester is a solar cell IV tester.
